(19) United States
(12) Patent Application Publication
(10) Pub. No.: US 2005/0255390 A1
(43) Pub. Date: Nov. 17, 2005

(54) Photomask for the manufacturing of reflective bumps

(75) Inventors: Chien-Ting Lai, Miao-Li (TW); Jia-Pang Pang, Miao-Li (TW); Yung-Chang Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/131,023

(22) Filed: May 16, 2005

(30) Foreign Application Priority Data
May 14, 2004 (TW) 93113620

(51) Int. Cl. G03C 5/00; G03F 9/00

(52) U.S. Cl. 430/5; 430/322; 430/22

(57) ABSTRACT

A photomask for manufacturing a reflective bump includes a plurality of patterns, each of which includes a light-transmitting portion meshed with a light-shielding portion, one of the light-transmitting portion and the light-shielding portion being a block area, and including a plurality of protrusions arranged at one side thereof that adjoins the other of the light-transmitting portion and the light-shielding portion, the protrusions being arranged in a plane of the photomask.

### FIELD OF THE INVENTION

The present invention relates to the manufacturing of reflective bumps used in products such as reflective or transflective mode liquid crystal displays (LCDs), and particularly to the use of photomasks in such manufacturing.

### BACKGROUND

LCDs are usually categorized, according to the manner in which they transport light, into reflective mode, transmissive mode and transflective mode LCDs. Typical reflective or transflective mode LCDs include reflective bumps arranged on a substrate, for reflecting externally sourced light in order to illuminate the LCD. The structure and arrangement of the reflective bumps significantly influence the viewing angle and brightness of the LCD.

Referring to FIG. 11, a first kind of reflective bump is horizontally arranged at a planar base surface. If an incident angle of light is 20°, a reflected angle is −20°. To put it another way, a reflective ratio R has a largest value R1 when a measuring angle is −20°. Furthermore, a distribution curve of the reflective ratio R is very narrow, and is centered at or near the −20° value.

However, in a typical reflective or transflective mode LCD, it is desired that the reflective ratio R has a largest value R1 when the measuring angle is 0°. In order to gain the largest reflective ratio R1 when the measuring angle is 0°, a second kind of reflective bump has been developed, with the reflective bump having a surface inclination angle of about 10°. This enables light that would otherwise have a surface incident angle of 20° to be reflected at an angle of 0°. A relationship between a reflective ratio R and a measuring angle Q for the second kind of reflective bump is shown in FIG. 12.

Notwithstanding the above-described advantages of the second kind of reflective bump, as seen in FIG. 12, a distribution curve of the reflective ratio is still very narrow. Consequently, a reflective or transflective mode LCD using the second kind of reflective bump cannot obtain wide viewing angles. To solve this problem, a third kind of reflective bump has been developed. The third kind of reflective bump has a surface inclination angle of about 10° and has an arched surface. This enables the reflective bump to scatter light and obtain a wide viewing angle. Referring to FIG. 13, a relationship between a reflective ratio R and a measuring angle Q for the third kind of reflective bump is clearly different to the corresponding relationship for the second kind of reflective bump. The reflective ratio has a largest value R2 when the measuring angle is at or near 0°. As a consequence, an LCD using the third kind of reflective bump has high brightness and a wide viewing angle.

A typical method for the manufacturing of the third kind of reflective bump includes:
providing a substrate;
depositing a photosensitive layer on the substrate;
exposing the photosensitive layer using a pattern having a single hatch;
repeating the above exposing step a required number of times, each repeat involving using a pattern having a different single hatch;
developing the exposed photosensitive layer to obtain a stepped structure; and
heating the stepped structure in order that the stepped structure reflows and forms a plurality of bumps, each bump having an arched surface.

Furthermore, in order to form a plurality of reflective bumps, a reflective layer is deposited on the arched surfaces. Thus, a plurality of reflective bumps having arched surfaces is obtained.

The above-described method requires multiple steps of exposing the photosensitive layer using a unique pattern having a single hatch. This makes the method quite complex and time-consuming. To solve these problems, a modified method for manufacturing reflective bumps is provided by Chi Mei Optoelectronics Corporation. Referring to FIG. 14, the modified method uses a photomask 10 instead of patterns each having a single hatch. The photomask 10 comprises parallel light-shielding strips 11, 12, 13, 14 separated by slits 15, with the light-shielding strips 11, 12, 13, 14 have different widths.

Referring to FIG. 15, the photomask 10 is utilized for exposing a photosensitive layer 20 formed on a substrate 30 to light such as UV light. The slits 15 prevent some light from passing through the photomask 10. Accordingly, the photosensitive layer 20 is not substantially exposed at areas thereof corresponding to the slits 15. Thus, as shown in FIG. 16, a stepped structure comprising steps 21, 22, 23, and 24 can be produced. The stepped structure is then heated in order that the steps 21, 22, 23, and 24 reflow, thereby forming bumps comprising arched protrusions 21′, 22′, 23′, and 24′, as shown in FIG. 17. The arched protrusions 21′, 22′, 23′, and 24′ collectively define an inclination angle of θ.

However, light that passes through the slits 15 dissipates rapidly from center areas of the slits 15 to outer extremities of the slits 15, and thus a smoothness of the arched protrusions 21′, 22′, 23′, and 24′ may be considered unsatisfactory. Accordingly, a distribution curve (not shown) of a reflective ratio for a reflective bump having any of the arched protrusions 21′, 22′, 23′, and 24′ may be considered to be not smooth enough. In addition, the slits 15 are linear and parallel to each other. This means that the reflective bumps manufactured by using the photomask 10 generally have high brightness and a wide viewing angle only in a single direction corresponding to an alignment direction of the slits 15.

What is needed is a photomask which can be utilized for the manufacturing of reflective bumps having better optical performance.

### SUMMARY

In one embodiment, a photomask for manufacturing a reflective bump comprises a plurality of patterns, each of which comprises a light-transmitting portion meshed with a light-shielding portion, one of the light-transmitting portion and the light-shielding portion being a block area, and comprising a plurality of protrusions arranged at one side thereof that adjoins the other of the light-transmitting portion and the light-shielding portion, the protrusions being arranged in a plane of the photomask.

Because of a plurality of protrusions arranged at its one side in a plane of the photomask, the rectangular protrusions can prevent some UV light from passing through the photomask in the vicinity of the rectangular protrusions. In addition, the rectangular protrusions can also prevent UV light that passes therethrough from being rapidly dissipated from central areas of the protrusions to outer extremities of the protrusions. Overall, the rectangular protrusions provide a continuum of varying degrees of exposure to UV light in the vicinity of the rectangular protrusions. Accordingly, the reflective bumps manufactured by using the photomask are also smoothly curved. That is, a distribution curve of a reflective ratio of the reflective bumps is smooth. Furthermore, because each reflective bump has an arched surface, a liquid crystal display having the reflective bumps can provide high brightness and a wide viewing angle.

In another embodiment, a photomask for manufacturing a reflective bump includes a plurality of patterns, each of which comprises a light-transmitting portion incorporated with a light-shielding portion. One of the light-transmitting portions and the light-shielding portions is a block area, one side of which has a lower light-shielding capability than other portions.

Other objects, advantages, and novel features will become more apparent from the following detailed description when taken in conjunction with the accompanying drawings, in which:

### BRIEF DESCRIPTION OF THE DRAWINGS

FIG. 1 is a schematic, top view of part of a photomask for the manufacturing of reflective bumps, in accordance with a first embodiment of the present invention;

FIG. 2 is a schematic, side cross-sectional view of a photosensitive layer on a substrate being exposed to UV light passing through the photomask of FIG. 1;

FIG. 3 is an isometric view of three protrusions produced by the process shown in FIG. 2;

FIG. 4 is a side view of three bumps on the substrate, obtained by heating the protrusions of FIG. 3;

FIG. 5 is a schematic, top view of part of a photomask for the manufacturing of reflective bumps, in accordance with a second embodiment of the present invention;

FIG. 6 is a schematic, top view of a light shielding portion of a photomask pattern of a photomask for the manufacturing of reflective bumps, in accordance with a third embodiment of the present invention;

FIG. 7 is an isometric view of one of reflective bumps that can be produced by using the photomask of FIG. 6;

FIG. 8 is a schematic, top view of a light shielding portion of a photomask pattern of a photomask for the manufacturing of reflective bumps, in accordance with a fourth embodiment of the present invention;

FIG. 9 is a schematic, top view of a light shielding portion of a photomask pattern of a photomask for the manufacturing of reflective bumps, in accordance with a fifth embodiment of the present invention;

FIG. 10 is a schematic, top view of a light-shielding portion of a photomask pattern of a photomask for the manufacturing of reflective bumps, in accordance with a sixth embodiment of the present invention;

FIG. 11 is a graph of reflective ratio versus measuring angle, in respect of a first kind of conventional reflective bump;

FIG. 12 is a graph of reflective ratio versus measuring angle, in respect of a second kind of conventional reflective bump;

FIG. 13 is a graph of reflective ratio versus measuring angle, in respect of a third kind of conventional reflective bump;

FIG. 14 is a schematic, top view of part of a typical photomask for the manufacturing of reflective bumps;

FIG. 15 is a schematic, side cross-sectional view of a photosensitive layer on a substrate being exposed to UV light passing through the photomask of FIG. 14;

FIG. 16 is a side view of four steps on the substrate, produced by the process shown in FIG. 15; and

FIG. 17 is a reduced, isometric view of bumps obtained by heating steps such as the steps of FIG. 16, four of the bumps corresponding to the four steps of FIG. 16.

### DETAILED DESCRIPTION OF PREFERRED EMBODIMENTS

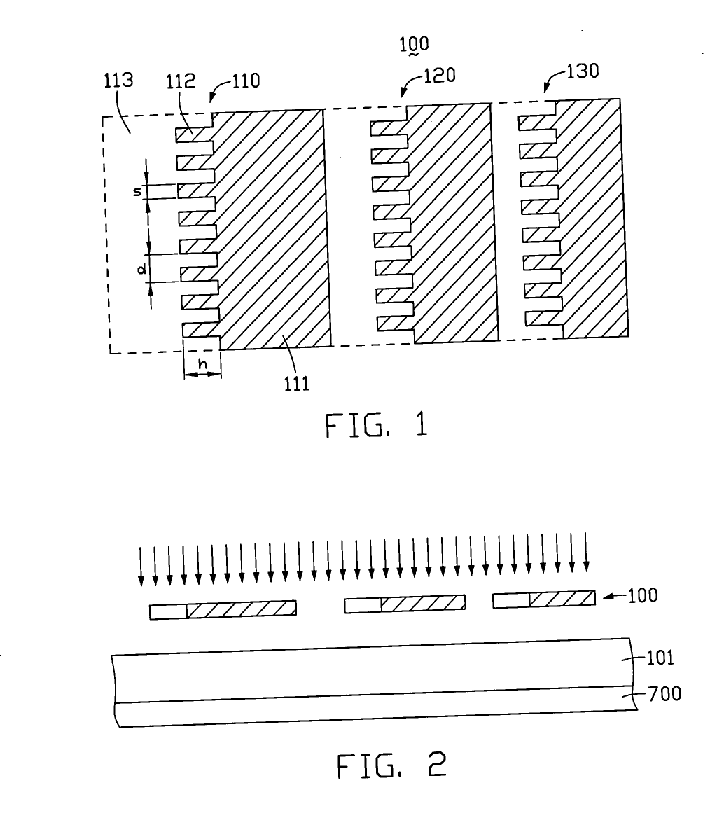

Referring to FIG. 1, a photomask 100 in accordance with a first embodiment of the present invention includes three photomask patterns 110, 120, and 130, which have different sizes. The photomask pattern 110 is rectangular, and includes a light-transmitting portion 113 meshing with a light-shielding portion 111. The light-shielding portion 111 is a generally rectangular block area. In alternative embodiments, the block area may be generally elliptical or circular. The light-shielding portion 111 has a plurality of rectangular protrusions 112 at one side thereof, the protrusions 112 being arranged in a plane of the photomask 100. Each rectangular protrusion 112 has a width ‘s’ of 1˜3 μm and a length ‘h’ of 1˜5 μm. In the illustrated embodiment, the width ‘s’ is about 1 μm and the length ‘h’ is about 2 μm. In addition, a pitch ‘d’ between any two adjacent rectangular protrusions 112 is about 2 μm.

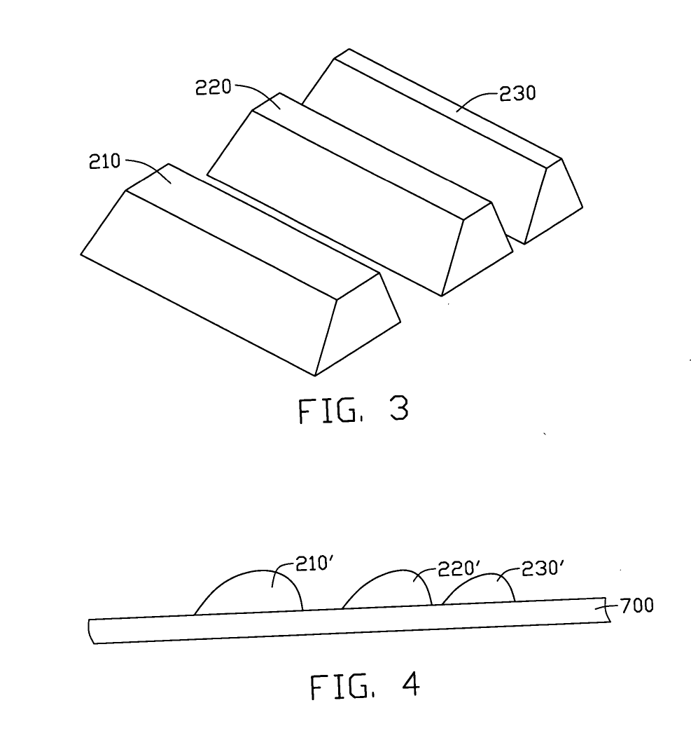

Referring also to FIGS. 2-4, an exemplary method for the manufacturing of a reflective bump using the photomask 100 includes:
providing a substrate 700;
depositing a photosensitive layer 101 on the substrate 700;
exposing the photosensitive layer 101 using the photomask 100 (see FIG. 2), the photomask 100 being arranged above the photosensitive layer 101 a predetermined distance, and light such as ultraviolet (UV) light being projected from a top side of the photomask 100 onto the photomask 100;
developing the exposed photosensitive layer 101 to obtain three protrusions 210, 220, and 230 (see FIG. 3) corresponding to the photomask patterns 110, 120, and 130; and
heating the three protrusions 210, 220, and 230 in order to obtain three bumps 210′, 220′, and 230′ (see FIG. 4), each of which has an arched surface.

Further, in order to obtain reflective bumps, a reflective layer is deposited on the arched surfaces.

The rectangular protrusions 112 can prevent some UV light from passing through the photomask 100 in the vicinity of the rectangular protrusions 112. Accordingly, the photosensitive layer 101 in the vicinity of the rectangular protrusions 112 is partially but not substantially exposed. The rectangular protrusions 112 can also help prevent lights that passes therethrough from being rapidly dissipated from central areas of the protrusions 112 to outer extremities of the protrusions 112. Overall, the rectangular protrusions 112 provide a continuum of varying degrees of exposure to UV light in the vicinity of the rectangular protrusions 112. This enables the bumps 210′, 220′, and 230′ to be smoothly curved. Accordingly, the reflective bumps are also smoothly curved. That is, a distribution curve of a reflective ratio of the reflective bumps is smooth. Furthermore, because each reflective bump has an arched surface, a liquid crystal display having the reflective bumps can provide high brightness and a wide viewing angle.

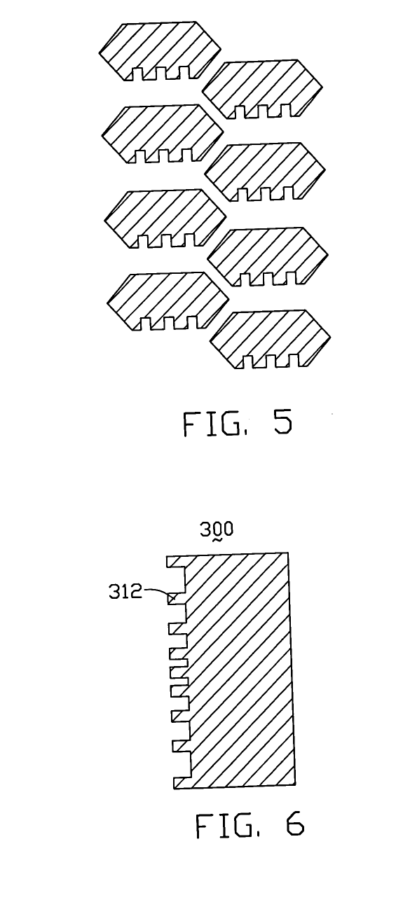

FIG. 5 illustrates a photomask 200 in accordance with a second embodiment of the present invention. The photomask 200 includes a plurality of photomask patterns. Each photomask pattern includes a generally hexagonal light-shielding portion, one side of which has a plurality of rectangular protrusions arranged in a plane of the photomask 200. Similar to the photomask 100, the photomask 200 provides high brightness and a wide viewing angle for a liquid crystal display, according to an alignment direction of the rectangular protrusions. In order to obtain high brightness and wide, multi-directional viewing angles, a plurality of rectangular protrusions can also be arranged at another one or more sides of each photomask pattern.

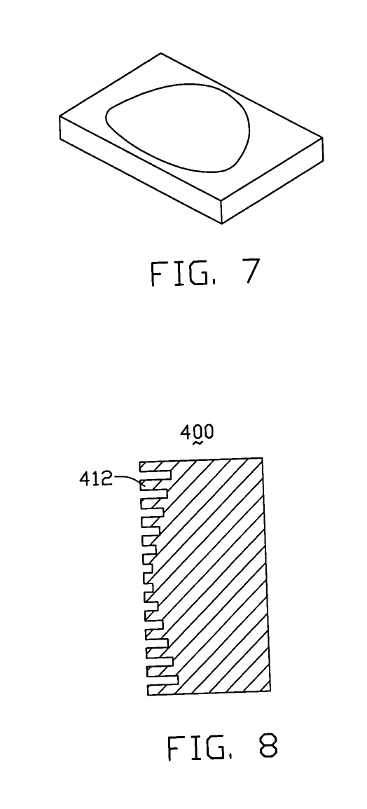

FIG. 6 illustrates a light shielding portion of a photomask pattern of a photomask 300 in accordance with a third embodiment of the present invention. The photomask 300 is similar to the photomask 100. The difference between the photomasks 300 and 100 is that the photomask 300 has a plurality of rectangular protrusions 312 arranged at a side of the photomask pattern, with a pitch between adjacent rectangular protrusions 312 not being constant. As illustrated in FIG. 6, the pitch between adjacent rectangular protrusions 312 progressively increases from a center of the arrangement of rectangular protrusions 312 to each of two opposite ends of the arrangement of rectangular protrusions 312. Therefore, the degree of exposure of a photosensitive layer in the vicinity of said two ends is higher than that of the photosensitive layer at said center. Accordingly, each reflective bump manufactured by using the photomask 300 can have smooth corners, as shown in FIG. 7. Consequently, the reflective bumps can provide better optical performance.

FIG. 8 illustrates a light shielding portion of a photomask pattern of a photomask 400 in accordance with a fourth embodiment of the present invention. The photomask 400 is similar to the photomask 100. The difference between the photomasks 400 and 100 is that the photomask 400 has a plurality of rectangular protrusions 412, with the rectangular protrusions 412 varying in length. As illustrated in FIG. 8, the lengths of the rectangular protrusions 412 progressively increase from a center of the arrangement of rectangular protrusions 412 to two opposite ends of the arrangement of rectangular protrusions 412. Similar to the photomask 300, reflective bumps manufactured by using the photomask 400 can have smooth corners, so that the reflective bumps can provide better optical performance.

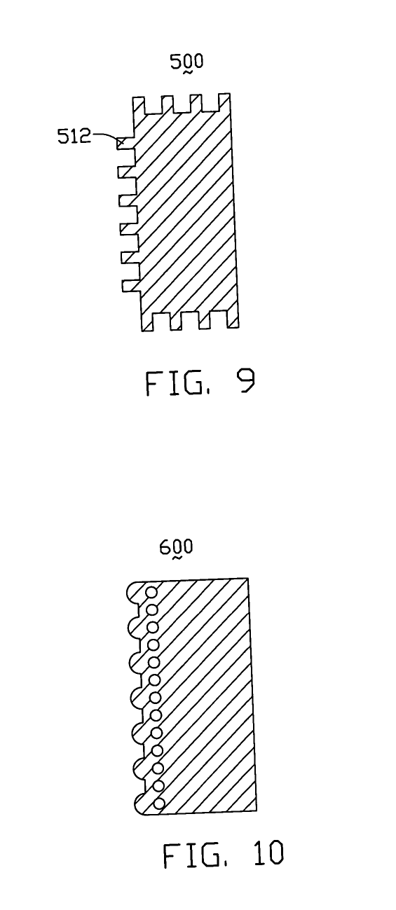

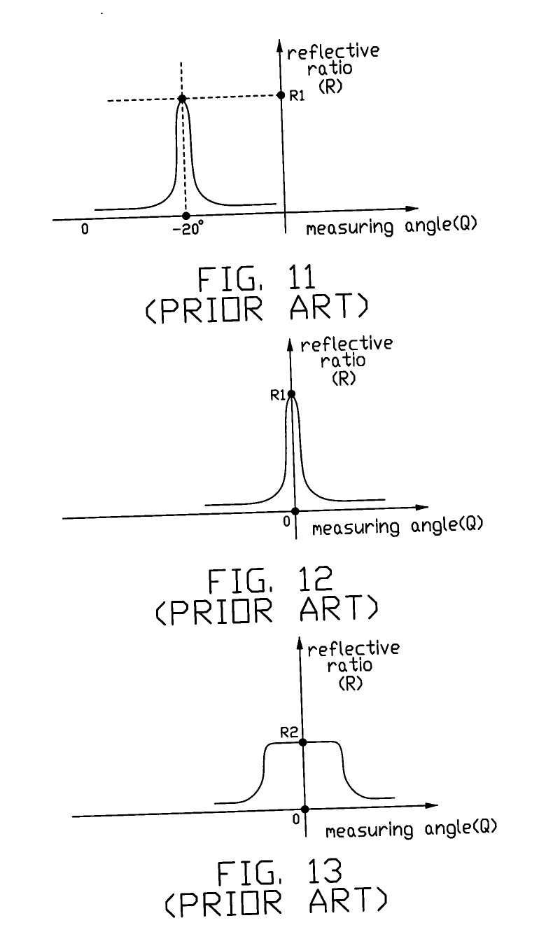

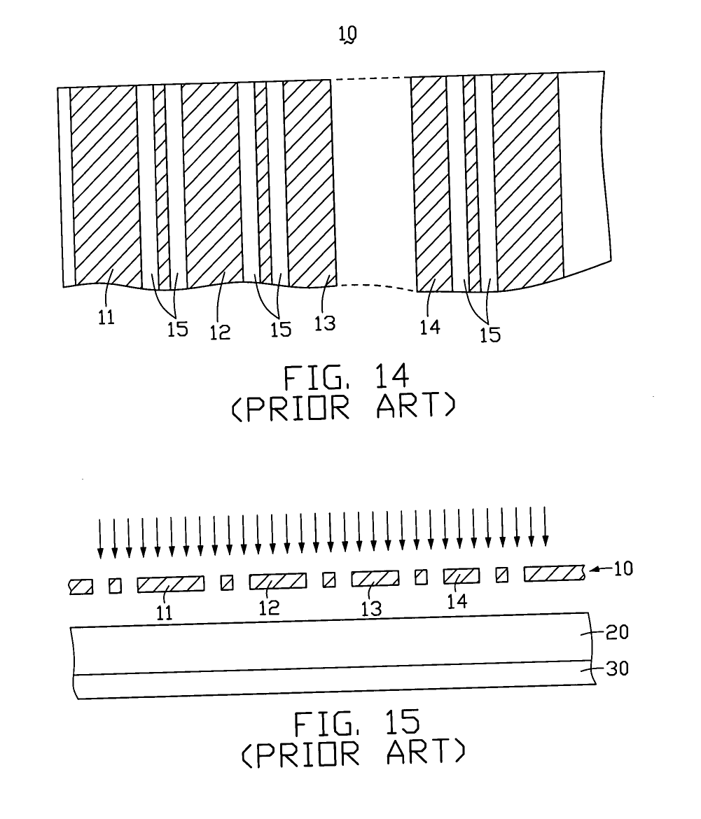

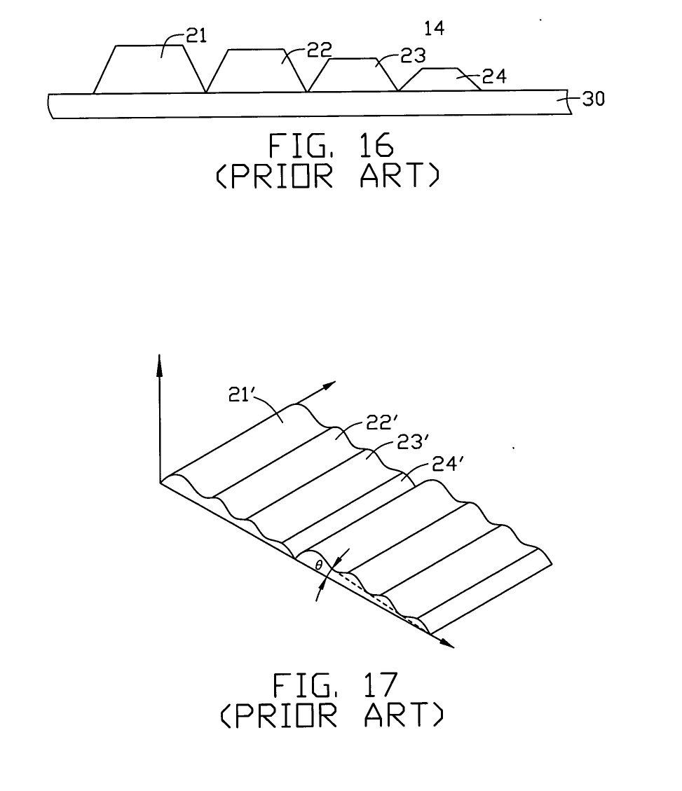

FIG. 9 illustrates a light shielding portion of a photomask pattern of a photomask 500 in accordance with a fifth embodiment of the present invention. The photomask 500 is similar to the photomask 100. The difference between the photomasks 500 and 100 is that the photomask 500 has a plurality of rectangular protrusions 512, with the rectangular protrusions 512 being arranged at three sides of the photomask 500. Similar to what is described above in relation to the photomask 200, reflective bumps manufactured by using the photomask 400 can provide high brightness and wide viewing angles for a liquid crystal display in respect of at least two alignment directions of the rectangular protrusions 512.

FIG. 10 illustrates a light-shielding portion of a photomask pattern of a photomask 600 in accordance with a sixth embodiment of the present invention. The photomask pattern includes a plurality of light-transmitting areas arranged at one side of the light-shielding portion. In the illustrated embodiment, each light-transmitting area is circular, and has a diameter of 1˜5 μm. A pitch between adjacent light-transmitting areas is constant. In an alternative embodiment, the pitch between adjacent light-transmitting areas can progressively decrease from each of two opposite ends of the arrangement of light-transmitting areas to a center of the arrangement of light-transmitting areas.

In another alternative embodiment, a photomask includes a plurality of photomask patterns. Each photomask pattern includes a first region, a second region and a third region consecutively arranged in that order. The first region is transparent. The second region is translucent. The third region is reflective. A light transmission ratio of the second region progressively decreases from one side of the second region adjacent the first region to an opposite side of the second region adjacent the third region. In a further alternative embodiment, the second region can be a light-shielding area that includes a plurality of light-transmitting points or sub-areas.

It is to be further understood that even though numerous characteristics and advantages of the embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

1. A photomask for the manufacturing of a reflective bump, comprising:
a plurality of patterns, each of which comprises a light-transmitting portion meshed with a light-shielding portion, one of the light-transmitting portion and the light-shielding portion being a block area, and comprising a plurality of protrusions arranged at one side thereof that adjoins the other of the light-transmitting portion and the light-shielding portion, the protrusions being arranged in a plane of the photomask.

2. The photomask as claimed in claim 1, wherein the block area is generally polygonal.

3. The photomask as claimed in claim 2, wherein the block area is generally rectangular.

4. The photomask as claimed in claim 1, wherein the protrusions are rectangular.

5. The photomask as claimed in claim 1, wherein the protrusions have a same size.

6. The photomask as claimed in claim 1, wherein the protrusions are regularly arranged.

7. The photomask as claimed in claim 1, wherein a pitch between adjacent protrusions progressively increases from a center of the arrangement of protrusions to each of two opposite ends of the arrangement of protrusions.

8. The photomask as claimed in claim 1, wherein lengths of the protrusions progressively increase from a center of the arrangement of protrusions to each of two opposite ends of the arrangement of protrusions.

9. A photomask for the manufacturing of a reflective bump, comprising:
a plurality of patterns, each of which comprises a light-transmitting portion meshed with a light-shielding portion, one of the light-transmitting portion and the light-shielding portion being a block area, and comprising one side section that adjoins the other of the light-transmitting portion and the light-shielding portion, the side section having a lower light-shielding capability than a remaining section of the one of the light-transmitting portion and the light-shielding portion.

10. The photomask as claimed in claim 9, wherein the side section comprises translucent material.

11. The photomask as claimed in claim 10, wherein a transparence of the side section progressively decreases from the light-transmitting portion to the light-shielding portion.

12. The photomask as claimed in claim 9, wherein the side section comprises a plurality of light-transmitting areas.

13. The photomask as claimed in claim 12, wherein the light-transmitting areas are circular.

14. The photomask as claimed in claim 13, wherein the light-transmitting areas have a same diameter, which is in the range from 1·5 μm.
